(19) United States
(12) Patent Application Publication
(10) Pub. No.: US 2006/0191711 A1
(43) Pub. Date: Aug. 31, 2006

(54) Embedded chip printed circuit board and method of manufacturing the same

(75) Inventors: Suk Hyeon Cho, Daejeon (KR); Chang Sup Ryu, Daejeon (KR); Jin Yong Ahn, Daejeon (KR)

Correspondence Address: DARBY & DARBY P.C., P. O. BOX 5257, NEW YORK, NY, 10150-5257, US

(73) Assignee: Samsung Electro-Mechanics Co., Ltd., Gyeonggi-do (KR)

(21) Appl. No.: 11/351,938

(22) Filed: Feb. 10, 2006

(30) Foreign Application Priority Data
Feb. 28, 2005 (KR) 10-2005-0016928

(51) Int. Cl. H05K 1/18; H05K 3/30; H01L 23/12

(52) U.S. Cl. 174/260; 174/262; 257/698; 361/764; 29/832; 29/852; 438/125

(57) ABSTRACT

The present invention relates to an embedded chip printed circuit board in which a space required for embedding a chip is formed to a desired depth depending on various thicknesses of chips to be embedded, and thus, the circuit line for the electrical connection between the embedded chip and the circuit pattern layer can be formed to be relatively short, thereby maximizing space efficiency and decreasing inductance at high frequencies. In addition, a method of manufacturing such an embedded printed circuit board is also provided.

### INCORPORATION BY REFERENCE

The present application claims priority under 35 U.S.C. §119 to Korean Patent Application No. 10-2005-0016928 filed on Feb. 28, 2005. The content of the application is incorporated herein by reference in its entirety.

### BACKGROUND OF THE INVENTION

1. Field of the Invention

The present invention relates, generally, to an embedded chip printed circuit board and a method of manufacturing the same. More particularly, the present invention relates to an embedded chip printed circuit board, in which the connection length between a chip and a circuit line is decreased to improve the degree of integration, and to a method of manufacturing such an embedded chip printed circuit board.

2. Description of the Related Art

With the recent improvement of electronic industries, in order to correspond to electronic products requiring miniaturization and high functionality, electronic technologies have been developed to insert resistors, capacitors, ICs (integrated circuits), etc., into substrates.

Although discrete chip resistors or discrete chip capacitors have long since been mounted on a printed circuit board (PCB), a PCB having embedded chip parts, such as resistors or capacitors, has only recently been developed.

In techniques for manufacturing a PCB having embedded chip parts, the chip parts, such as resistors or capacitors, are inserted into an inner layer of the substrate using novel materials and processes, to substitute for conventional passive parts, such as chip resistors and chip capacitors, mounted on the PCBs.

That is, the PCB having embedded chips means that the capacitors in chip form are embedded in the inner layer of the substrate itself. Regardless of the size of the substrate itself, if the chip is incorporated into a portion of PCB, this is called an ‘embedded chip’. Such a substrate is referred to as an ‘embedded chip PCB’.

The most important characteristic of the embedded chip PCB is that an electronic part that has been externally manufactured and confirmed to have certain performance is inserted, thus maintaining a more stable yield than when directly manufacturing such a part on the substrate.

Techniques for manufacturing the embedded chip PCB developed to date are largely classified into three types.

First, a method of manufacturing a polymer thick film type capacitor is provided, including applying a polymer capacitor paste, which is then heat-cured, that is, dried. Specifically, this method includes applying a polymer capacitor paste on the inner layer of a PCB, and drying the polymer capacitor paste, on which a copper paste is then printed and dried to form electrodes, thereby obtaining an embedded capacitor.

Second, a method of manufacturing an embedded discrete type capacitor is provided, including coating a PCB with a ceramic filled photo-dielectric resin, which has been patented by Motorola Co. Ltd., USA. The method includes applying the photo-dielectric resin containing ceramic powder onto the substrate, laminating copper foils on upper and lower surfaces of the resin layer to form an upper electrode and a lower electrode, forming a circuit pattern, and then etching the photo-dielectric resin, thereby realizing a discrete capacitor.

Third, a method of manufacturing an embedded capacitor is provided, including separately inserting a dielectric layer having capacitance properties into the inner layer of a PCB so as to substitute for a decoupling capacitor mounted on a PCB, which has been patented by Sanmina Co. Ltd., USA. In this method, the dielectric layer having a power electrode and a ground electrode is inserted into the inner layer of the PCB, thereby realizing a power-distributed decoupling capacitor.

FIGS. 1A to 1F are cross-sectional views sequentially showing a conventional process of manufacturing an embedded chip PCB, which is disclosed in Japanese Patent Laid-open Publication No. 2002-118366.

As shown in FIG. 1A, a core substrate 10 having a predetermined circuit pattern is processed to form a hollow region 11 in which a chip is then embedded, and an adhesive 12 is applied on the bottom surface of the hollow region 11.

As shown in FIG. 1B, a chip 13 is placed on the adhesive 12 and is thus held in the hollow region 11.

After the chip 13 is held in the hollow region 11, as shown in FIG. 1C, the space between the chip 13 and the inner wall of the hollow region 11 is filled with a thermosetting resin 14.

As shown in FIG. 1D, a thermosetting epoxy resin sheet is laminated on the core substrate 10 and then vacuum compressed at 50-150° C. under 5 kg/cm² to form a resin insulating layer 15.

After the resin insulating layer 15 is formed, as shown in FIG. 1E, the resin insulating layer 15 is processed using a laser to form via holes 16 for use in electrical connection of a first electrode and a second electrode of the chip 13.

As shown in FIG. 1F, an embedded chip PCB 17 is manufactured using a typical PCB building-up process.

However, the conventional method of manufacturing an embedded chip PCB is disadvantageous because the chip is embedded, the resin insulating layer is laminated, and the via holes are formed to electrically connect the chip to the circuit layer, resulting in a lone circuit connection line and a large circuit space. Consequently, it is difficult to manufacture an embedded chip PCB which is light, slim, short and small.

In addition, the conventional method of manufacturing an embedded chip PCB suffers because it has high inductance due to the extensive length of its circuit line.

### SUMMARY OF THE INVENTION

Accordingly, the present invention has been made keeping in mind the above problems occurring in the related art, and an object of the present invention is to provide an embedded chip PCB, which is highly dense and is light, slim, short and small by forming the connection line between a chip and a circuit line to be relatively short.

Another object of the present invention is to provide a method of manufacturing such an embedded chip PCB.

In order to accomplish the above objects, the present invention provides an embedded chip PCB, including a core layer, which includes a copper clad laminate (CCL) having a hollow region opening at one surface thereof, a chip embedded in the CCL, an inner circuit pattern layer formed on each of upper and lower surfaces of the CCL, and a via hole for electrical connection between the inner circuit pattern layer and the chip; an insulating layer formed on each of upper and lower surfaces of the core layer and having a via hole formed therethrough; and an outer circuit pattern layer formed on the insulating layer.

In addition, the present invention provides a method of manufacturing an embedded chip PCB, including the steps of forming a hollow region at one surface of a CCL such that the hollow region opens at the one surface thereof; applying a polymer material on a bottom surface of the hollow region of the CCL and then placing a chip on the polymer material in the hollow region of the CCL; filling a space of the hollow region other than a space occupied by the chip with a polymer material and then leveling the surface of the space; forming a via hole through the CCL having the chip and then plating or fill-plating the via hole; forming an inner circuit pattern layer on the CCL using a photolithographic process; and laminating an insulating layer on the inner circuit pattern layer, forming a via hole, and then forming an outer circuit pattern layer using a semi-additive process.

In addition, the present invention provides a method of manufacturing an embedded chip PCB, including the steps of forming a hollow region at one surface of a CCL such that the hollow region opens at the one surface thereof; applying a polymer material on a bottom surface of the hollow region of the CCL and then placing a chip on the polymer material in the hollow region of the CCL; filling a space of the hollow region other than a space occupied by the chip with a polymer material and leveling the surface of the space; forming a via hole through the CCL having the chip and plating or fill-plating the via hole; forming an inner circuit pattern layer on the CCL using a photolithographic process; sequentially laminating an insulating layer and a copper foil on the inner circuit pattern layer or laminating a resin coated copper (RCC) having an insulating layer and a copper foil applied on either surface of the insulating layer on the inner circuit pattern layer, forming a via hole, and then plating or fill-plating the via hole; and forming an outer circuit pattern layer on the RCC using a photolithographic process.

### BRIEF DESCRIPTION OF THE DRAWINGS

The above and other objects, features and advantages of the present invention will be more clearly understood from the following detailed description taken in conjunction with the accompanying drawings, in which:

FIGS. 1A to 1F are cross-sectional views sequentially showing a conventional process of manufacturing an embedded chip PCB;

FIG. 2 is a cross-sectional view showing an embedded chip PCB, according to the present invention;

FIGS. 3A to 3M are cross-sectional views sequentially showing a process of manufacturing an embedded chip PCB, according to an embodiment of the present invention;

FIGS. 4A to 4C are cross-sectional views showing hollow regions having embedded chips, according to the present invention;

FIGS. 5A to 5L are cross-sectional views sequentially showing a process of manufacturing an embedded chip PCB, according to another embodiment of the present invention;

FIG. 6A is a view showing the variation in voltage depending on a period of time at high frequencies of a conventional embedded chip PCB; and

FIG. 6B is a view showing the variation in voltage depending on a period of time at high frequencies of the embedded chip PCB of the present invention.

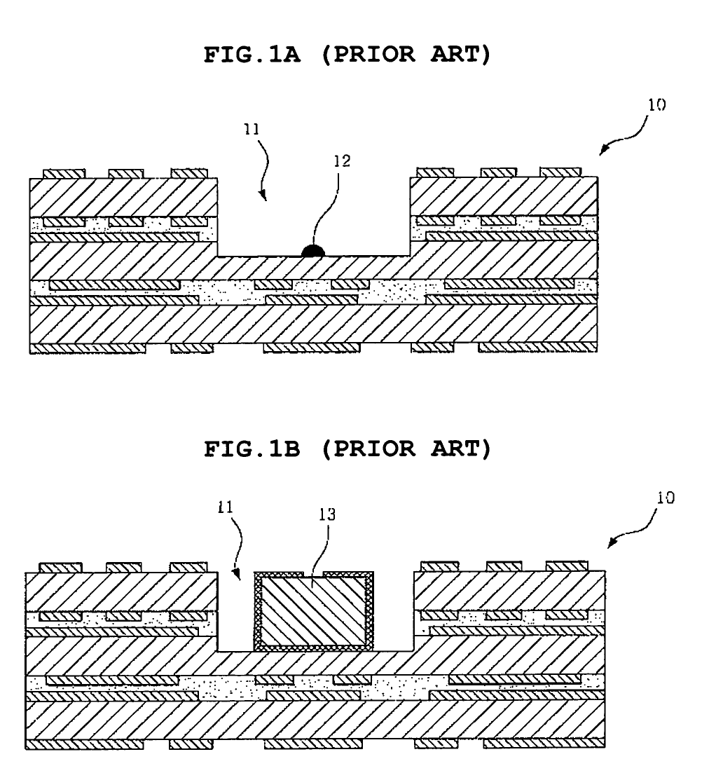

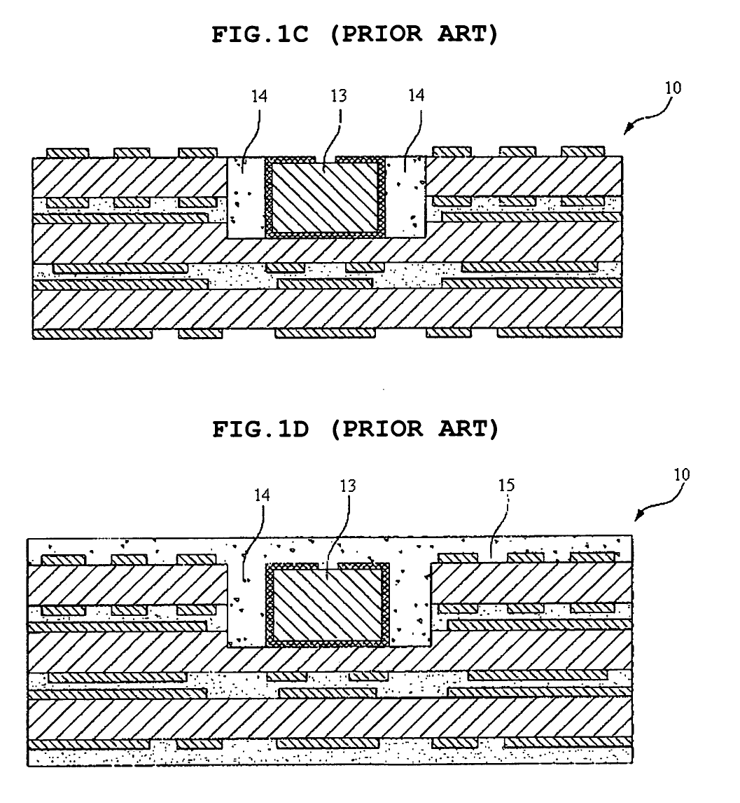

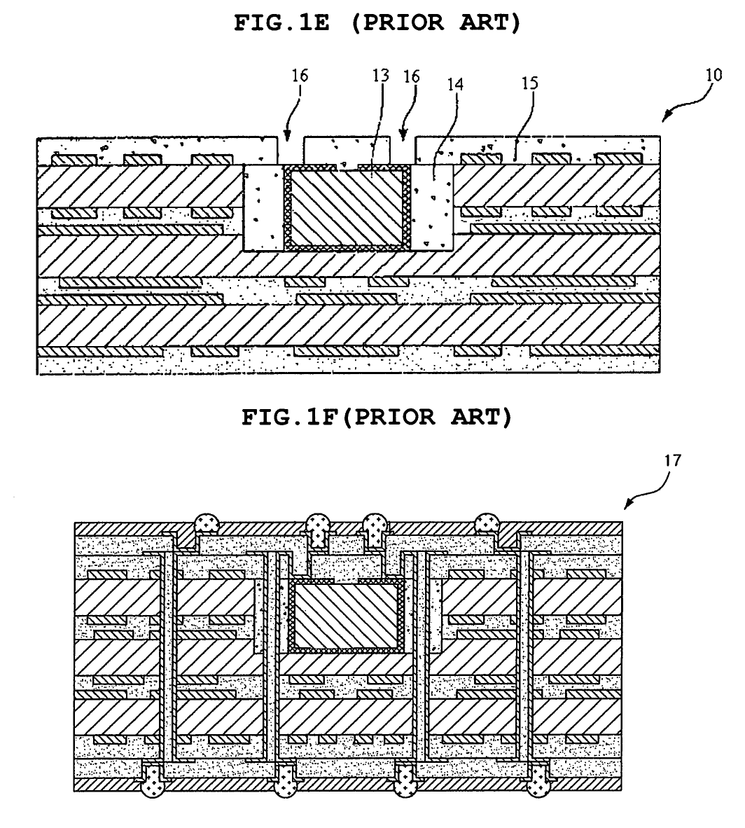

### DETAILED DESCRIPTION OF THE INVENTION

Hereinafter, a detailed description will be given of an embedded chip PCB and a method of manufacturing the same, according to the present invention, with reference to the appended drawings.

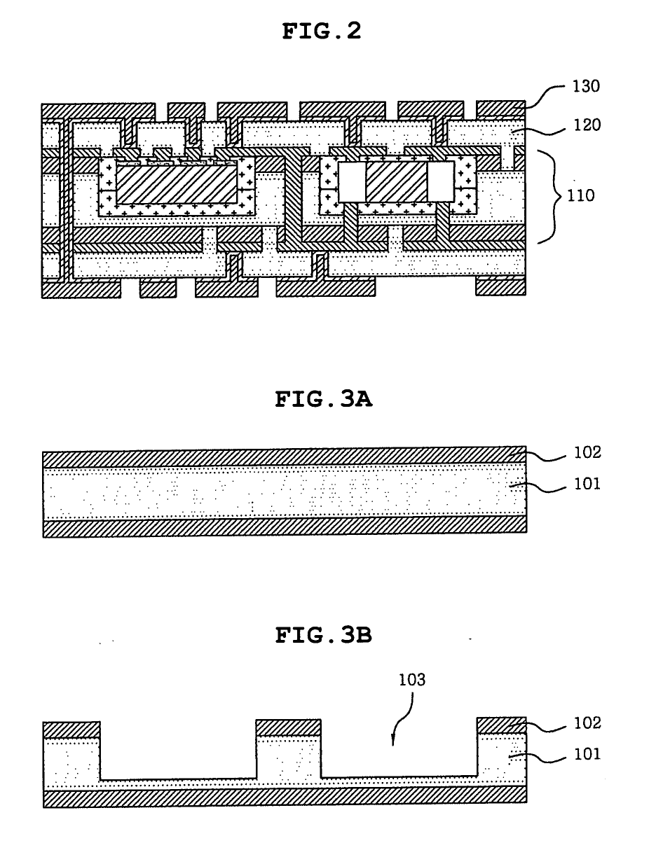

FIG. 2 is a cross-sectional view showing an embedded chip PCB, according to the present invention.

As shown in FIG. 2, the embedded chip PCB, according to the present invention, includes a core layer 110, which includes a CCL having an insulating layer and thin copper foils provided on both surfaces thereof, chips embedded in the CCL, inner circuit pattern layers formed on upper and lower surfaces of the CCL, and via holes for use in the electrical connection of the inner circuit pattern layers and the embedded chips. In addition, the embedded chip PCB includes an insulating layer 120 laminated on each of the upper and lower surfaces of the core layer 110 and having via holes formed therethrough, and an outer circuit pattern layer 130 laminated on the insulating layer 120 and having an outer circuit pattern.

That is, the core layer 110 is provided by drilling the upper surface of the CCL to form a hollow region opening at the upper surface thereof, into which the chip is then embedded, by forming the via holes for electrical connection between the inner circuit pattern layers and between the chip and the inner circuit pattern layer through the CCL, and by forming the inner circuit pattern layers on the upper and lower surfaces of the CCL.

The hollow region of the CCL is formed to be deeper than the height of chip, and thus the space of the hollow region other than the space occupied by the chip is filled with a polymer material.

The via hole of the core layer 110 includes a through hole for use in electrical connection of the inner circuit pattern layers and a blind via hole for use in electrical connection of the chip and the inner circuit pattern layer.

The insulating layer 120 is formed on each of the upper and lower surfaces of the core layer 110 and includes via holes for use in electrical connection of the core layer 110 and the outer circuit pattern layer 130.

The outer circuit pattern layer 130 has the outer circuit pattern formed on the insulating layer 120.

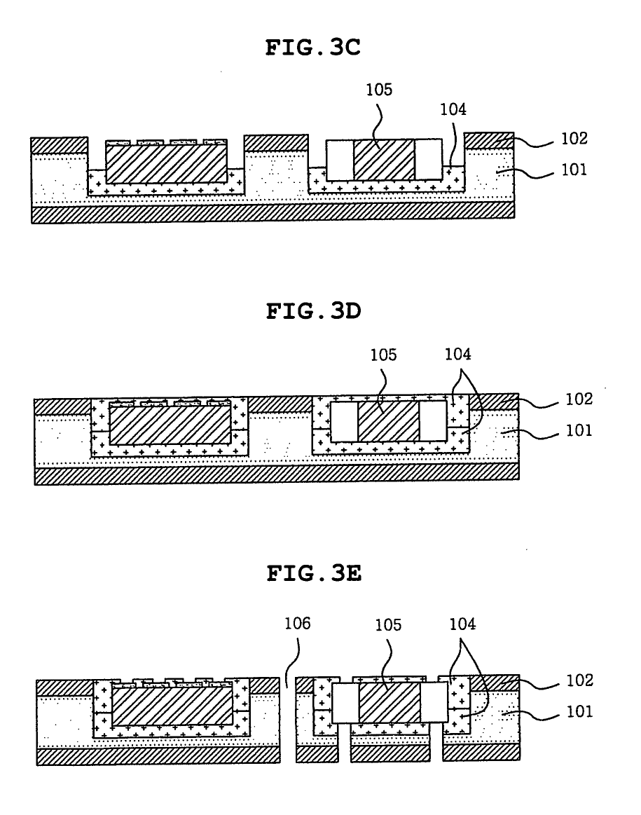

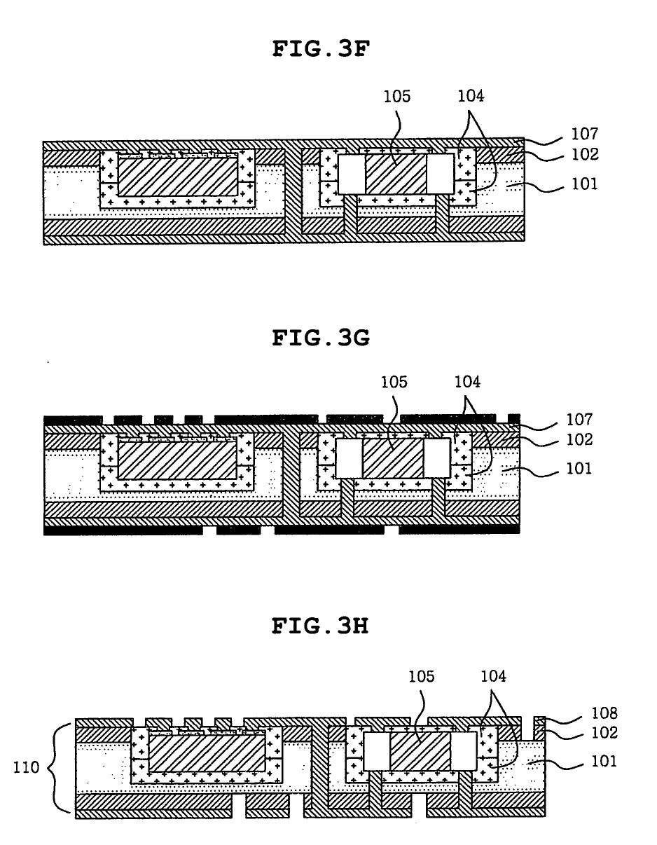

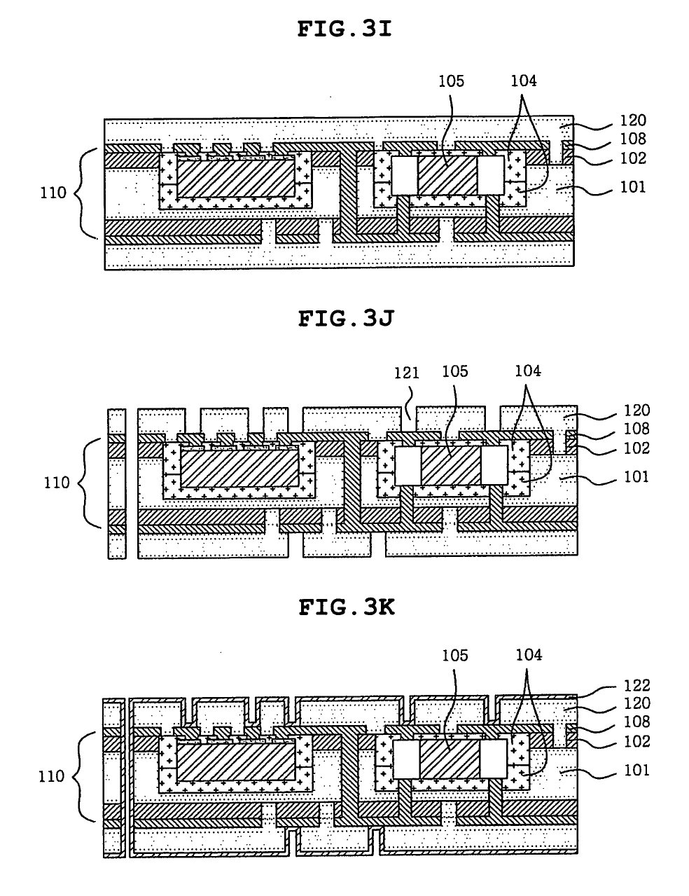

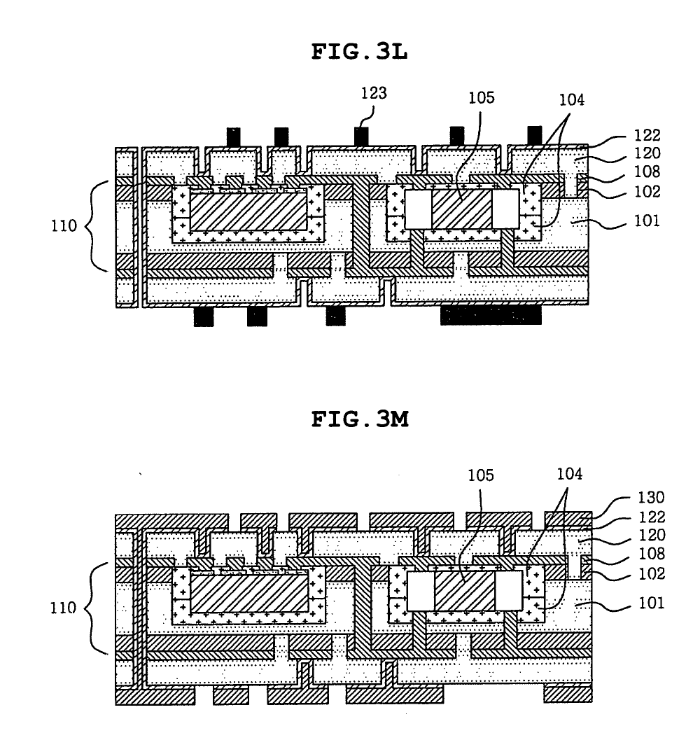

FIGS. 3A to 3M sequentially illustrate a process of manufacturing an embedded chip PCB, according to an embodiment of the present invention.

As shown in FIG. 3A, a CCL, including an insulating layer 101 and thin copper foils 102 formed on both surfaces thereof, is provided.

The insulating layer 101 of the CCL is formed of composite material including resin and glass fabric, which is material having excellent electrical properties and high strength in all directions but not having the disadvantages of resin having insufficient mechanical strength and dimensional variation by a temperature (coefficient of thermal expansion) 10 times larger than that of metal. The copper foil 102 is formed on such an insulating layer 101 using a process of thinly plating copper on a rotating cathode drum through electrolysis and then peeling it from the cathode, thus providing the CCL.

Alternatively, instead of the CCL, a base substrate having a desired number of insulating layers and a desired number of copper layers may be used.

As shown in FIG. 3B, the upper surface of the CCL is processed through a drilling process to form hollow regions 103, each of which opens at the upper surface of the CCL and is deeper than the height of the chip.

The drilling process may be conducted using a YAG (Yttrium Aluminum Garnet) laser or a C0₂ laser. Further, when the CCL is processed to the desired depth of the copper foil or insulating layer thereof, a drill bit acting to control the depth may be used to obtain such a desired depth.

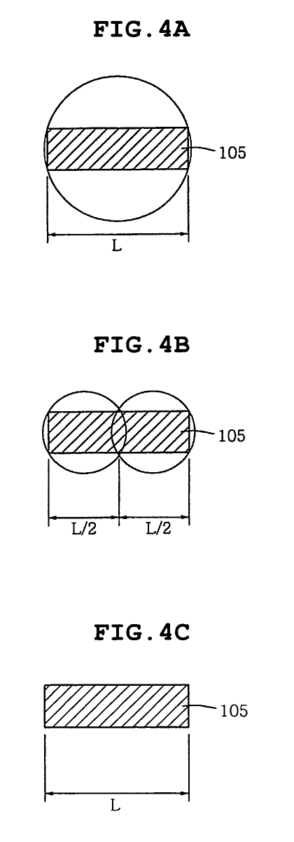

The drill bit may be used once or twice depending on the size thereof, in consideration of the size of chip to be subsequently embedded, to form a desired hollow region, as can be seen in FIGS. 4A to 4C. In addition, the C0₂ laser may be used to form the hollow region of the CCL to be slightly larger than the size of the chip 105. The hollow region 103 is processed to be deeper than the height of the chip to be embedded therein, thus enabling the formation of the via hole between the chip and the inner circuit pattern layer.

After the hollow region 103 is formed, as shown in FIG. 3C, a predetermined polymer material 104 is applied on the bottom surface of the hollow region 103 and a chip 105 is then placed on the polymer material 104 in the hollow region 103 of the CCL.

The polymer material 104, which is liquid epoxy material, is used to hold the chip 105 on the substrate.

As shown in FIG. 3D, the space of the hollow region 103 other than the space occupied by the chip 105 is filled with the polymer material 104, the upper surface of which is leveled to be as high as the copper foil.

In this way, the space of the hollow region 103 other than the space occupied by the chip 105 is filled with the polymer material 104, thus forming a predetermined insulating layer. Thereby, a connection line between the chip and the circuit, which is subsequently formed, can be formed to be relatively short. That is, the chip can be directly connected to the copper foil of the layer in which the above chip is embedded without via holes passing through the other layers.

Thereafter, as shown in FIG. 3E, via holes 106 are formed.

The via hole 106 is formed into a through hole using a mechanical drilling process or into a blind via hole precisely formed using a laser drill such as a YAG laser or C0₂ laser.

After the via holes 106 are formed, as shown in FIG. 3F, electroless copper plating and copper electroplating are conducted to plate or fill-plate the inner portion of the via hole, thus forming a plating layer 107.

The reason why the copper electroplating is conducted after the electroless copper plating is that the inner wall of the drilled hole, which is formed of insulating material, is not subjected to copper electroplating through electrolysis, and thus, the electroless copper plating through deposition precedes the copper electroplating. In addition, only the electroless plating layer is difficult to use since it is thin and has poor properties. Hence, the electroless plating layer should be coated with a copper electroplating layer to alleviate the drawbacks thereof.

Alternatively, instead of the inner portion of the via hole 106 being fill-plating, the via hole 106 may be filled with conductive ink, leveled and then plated.

As shown in FIGS. 3G and 3H, an inner circuit pattern layer 108 is formed using a photolithographic process.

The photolithographic process is used to transfer the circuit pattern printed on an artwork film onto a substrate. Various transferring processes may be provided. Among these processes, a process of transferring a circuit pattern from an artwork film to a photosensitive dry film through UV light is commonly used.

The dry film, having the transferred circuit pattern, functions as an etching resist. Through the etching treatment, the copper foil, corresponding to the region where the etching resist pattern is not formed, is removed, thus completing the core layer 110 having the inner circuit pattern layers 108.

Subsequently, as shown in FIG. 3I, an insulating layer 120 is laminated on each of the upper and lower surfaces of the core layer 110.

As the insulating layer 120, a partially cured prepreg is used, which is formed of composite material including glass fabric and thermosetting resin to be cured by predetermined amounts of heat and pressure.

After the insulating layer 120 is laminated, as shown in FIG. 3J, via holes 121 are formed through the insulating layer 120 using a drilling process.

As shown in FIG. 3K, a seed layer 122 is formed using an electroless plating process.

In order to form a highly dense circuit pattern, the plating layer constituting the seed layer 122 is formed not only to be thin but also to be uniformly distributed in the via hole 121.

Although the electroless plating is mainly conducted using copper, other metals, such as nickel or tin, may be used as long as electroless plating may be conducted.

After the seed layer 122 is formed, as shown in FIG. 3L, a resist pattern 123 is formed.

The resist pattern serves to form an outer circuit pattern using a process of transferring a circuit pattern from an artwork film to the substrate using a photosensitive dry film through UV light.

As shown in FIG. 3M, a copper plating process is conducted and the resist pattern 123 is removed, after which the opened seed layer 120 is etched, thus completing an outer circuit pattern layer 130.

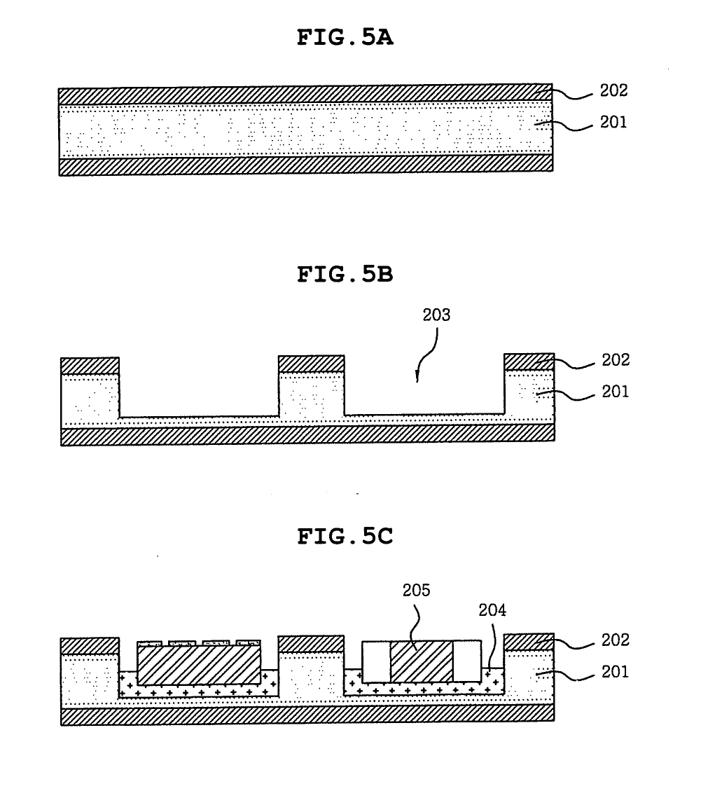

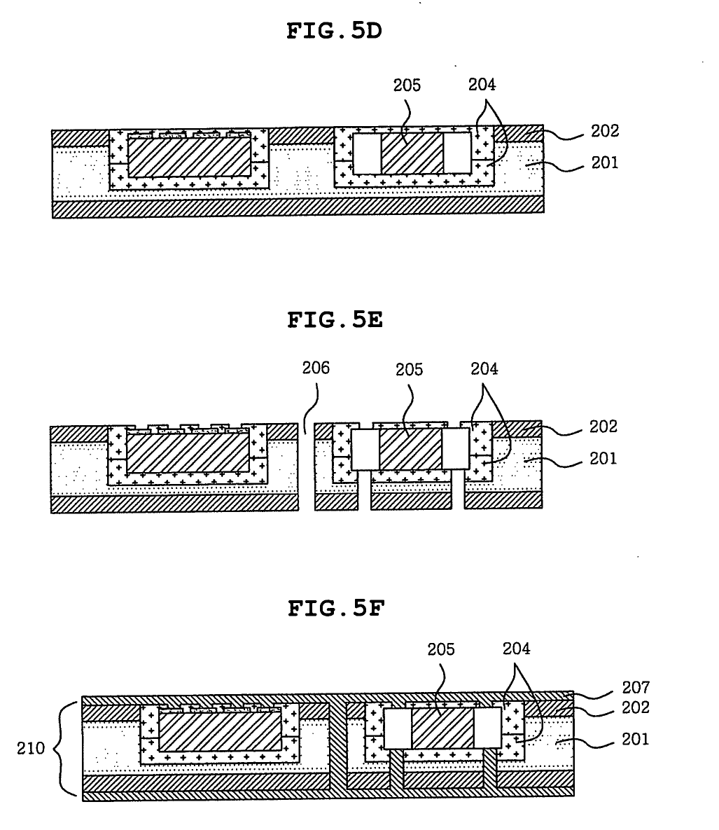

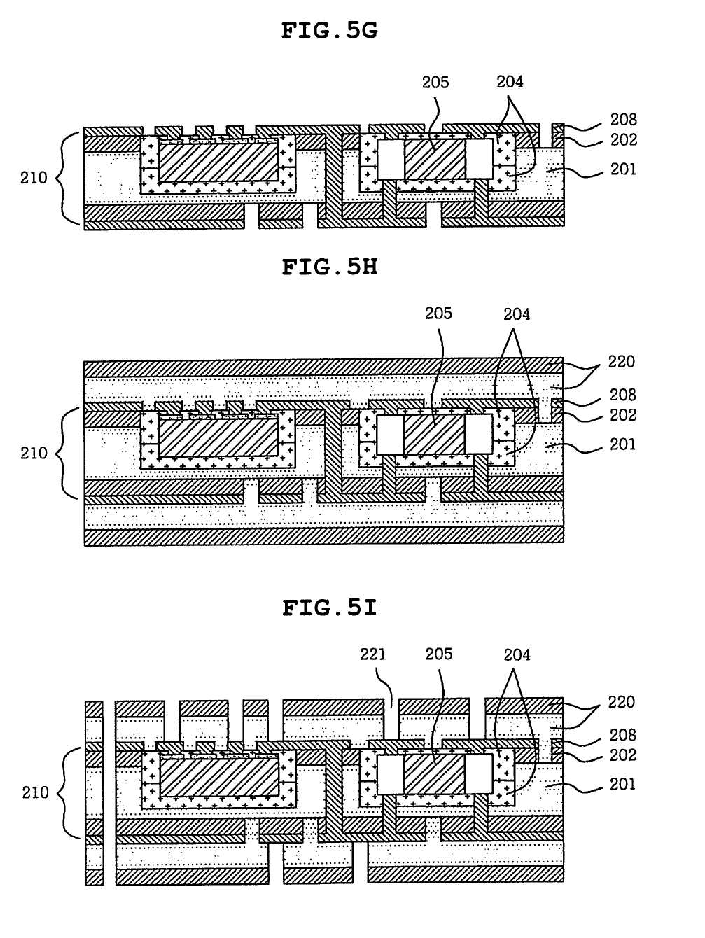

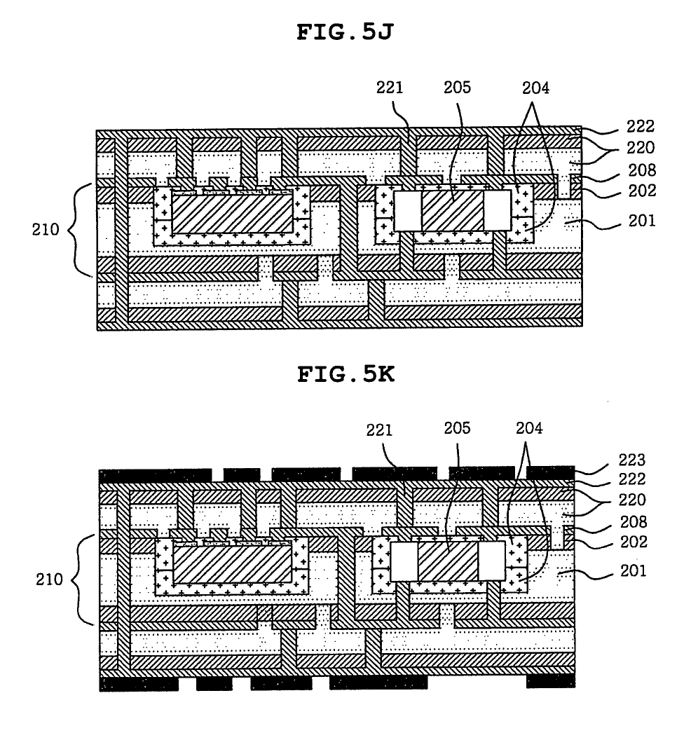

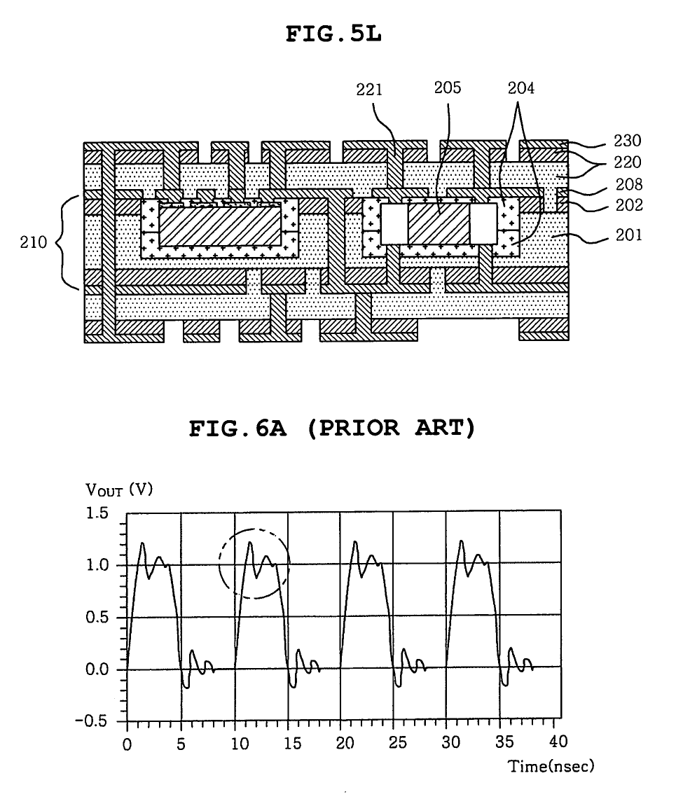

Turning now to FIGS. 5A to 5L, a process of manufacturing an embedded chip PCB according to another embodiment of the present invention is sequentially illustrated.

As shown in FIG. 5A, a CCL, including an insulating layer 201 and thin copper foils formed on both surfaces thereof, is provided.

The insulating layer 201 of the CCL is formed of composite material including resin and glass fabric, which is material having excellent electrical properties and high strength in all directions but not having the disadvantages of resin having insufficient mechanical strength and dimensional variation by a temperature (coefficient of thermal expansion) 10 times larger than that of metal. The copper foil 202 is formed on such an insulating layer 201 using a process of thinly plating copper on a rotating cathode drum through electrolysis and then peeling it from the cathode, thus providing the CCL.

Alternatively, instead of the CCL, a base substrate having a desired number of insulating layers and a desired number of copper layers may be used.

As shown in FIG. 5B, the upper surface of the CCL is processed through a drilling process to form hollow regions 203, each of which opens at the upper surface of the CCL.

The drilling process may be conducted using a YAG laser or a C0₂ laser. Further, when the CCL is processed to a desired depth of the copper foil or insulating layer thereof, a drill bit acting to control the depth may be used to obtain such a desired depth.

The drill bit may be used once or twice depending on the size thereof, in consideration of the size of chip to be subsequently embedded, to process a desired hollow region, as can be seen in FIGS. 4A to 4C. In addition, the C0₂ laser may be used to process the hollow region of the CCL to be slightly larger than the size of the chip 205.

After the hollow region 203 is formed, as shown in FIG. 5C, a predetermined polymer material 204 is applied on the bottom surface of the hollow region 203 of the CCL and a chip 205 is then placed on the polymer material 204 in the hollow region 203 of the CCL.

The polymer material 204, which is liquid epoxy material, is used to hold the chip 205 on the substrate.

As shown in FIG. 5D, the space of the hollow region 203 other than the space occupied by the chip 205 is filled with the polymer material 204, the upper surface of which is leveled to be as high as the copper foil.

In this way, the space of the hollow region 203 other than the space occupied by the chip 205 is filled with the polymer material 204, whereby a connection line between the chip and the circuit, which is subsequently formed, can be formed to be relatively short. That is, the chip can be directly connected to the copper foil of the layer in which the above chip is embedded without via holes passing through the other layers.

Thereafter, as shown in FIG. 5E, via holes 206 are formed.

The via hole 206 is formed into a through hole using a mechanical drilling process or into a blind via hole precisely formed using a laser drill, such as a YAG laser or C0₂ laser.

After the via holes 206 are formed, as shown in FIG. 5F, electroless copper plating and copper electroplating are conducted to plate or fill-plate the inner portion of the via hole 206, thus forming a plating layer 207.

The reason why the electroless copper plating and then copper electroplating are conducted is that the inner wall of the drilled hole, which is formed of insulating material, is not subjected to copper electroplating through electrolysis, and thus, the electroless copper plating through deposition precedes the copper electroplating. In addition, only the electroless plating layer is difficult to use since it is thin and has poor properties. Hence, the electroless plating layer should be coated with a copper electroplating layer to alleviate the drawbacks thereof.

Alternatively, instead of the inner portion of the via hole 206 being fill-plated, the via hole 206 may be filled with conductive ink, leveled and then plated.

As shown in FIG. 5G, an inner circuit pattern layer 208 is formed using a photolithographic process.

The photolithographic process is used to transfer the circuit pattern printed on an artwork film onto a substrate. Various transferring processes may be provided. Among these processes, a process of transferring a circuit pattern from an artwork film to a photosensitive dry film through UV light is commonly used.

The dry film, having the transferred circuit pattern, functions as an etching resist. Through the etching treatment, the copper foil, corresponding to the region where the etching resist pattern is not formed, is removed, thus completing the core layer 210 having the inner circuit pattern layers 208.

As shown in FIG. 5H, an insulating layer and a copper foil are sequentially laminated on each of the upper and lower surfaces of the core layer 210 to form an RCC 220 thereon, or an RCC 220 including an insulating layer and a copper foil applied on either surface thereof is laminated on each of the upper and lower surfaces of the core layer 210.

In the RCC 220, which is a substrate including an insulating layer and a copper foil applied on either surface thereof, the resin layer functions for interlayer insulation and the copper foil is used to form an outer circuit pattern layer.

After the RCC 220 is laminated, as shown in FIG. 5I, via holes 221 are formed through a drilling process.

The via hole 221 is formed into a blind via hole for electrical connection of layers or into a through hole for connection of outer layers, using a laser drill or mechanical drill.

As shown in FIG. 5J, electroless plating and copper electroplating are conducted to plate or fill-plate the via hole 221, thus forming a plating layer 222.

Through the plating or fill-plating of the via hole 221, the layers are electrically connected to each other, and the plating layer 222 is formed into the outer circuit pattern layer along with the copper foil of the RCC 220.

Alternatively, the via hole 221 may be filled with conductive ink instead of being fill-plated, leveled and then plated.

After the plating layer 222 is formed, as shown in FIG. 5K, an etching resist pattern 223 is formed.

In order to form the etching resist pattern 223, a circuit pattern printed on an artwork film should be transferred onto the substrate. Among various transferring processes, a process of transferring a circuit pattern from an artwork film to a photosensitive dry film through UV light is commonly used. Recently, LPR (Liquid Photo Resist) may be used instead of the dry film.

The dry film or LPR having the transferred circuit pattern functions as the etching resist 223. When the substrate is dipped into an etching solution, as shown in FIG. 5L, the copper foil and the plating layer 222, corresponding to the region where the etching resist pattern 223 is not formed, are removed, thus completing an embedded chip PCB having predetermined outer circuit pattern layers 230.

In the present invention, the insulation of the chip from the inner circuit pattern layer is realized by filling the space corresponding to the difference in height between the chip and the hollow region with the polymer material, thus the connection line between the chip and the circuit line is formed to be relatively short.

Thereby, the circuit space including circuit lines, that is, surface space, is decreased and inductance may be reduced.

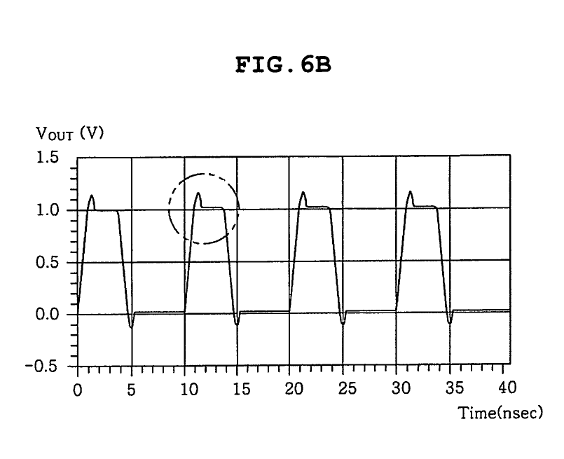

FIG. 6A illustrates the variation in voltage depending on a period of time at high frequencies in a conventional embedded chip PCB having a long connection line between a chip and a circuit line, whereas FIG. 6B illustrates the variation in voltage depending on a period of time at high frequencies in an embedded chip PCB of the present invention, in which wavelets are drastically decreased.

As described above, the present invention provides an embedded chip PCB and a method of manufacturing the same. According to the present invention, the via hole for electrical connection of the chip and the circuit line can be formed as thick as the difference in height between the chip and the hollow region formed for embedding the chip, whereby a surface space including circuit lines is reduced, thus increasing the degree of integration of the substrate. That is, the chip can be directly connected to the copper foil of the layer in which the above chip is embedded without via holes passing through the other layers.

In addition, the connection length between the chip and the circuit line is decreased, hence reducing inductance and wavelets of voltage at high frequencies.

Although the embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An embedded chip printed circuit board, comprising:
a core layer, which includes a copper clad laminate having upper and lower surfaces and a hollow region opening at one of the upper and lower surfaces thereof, a chip embedded in the copper clad laminate, an inner circuit pattern layer formed on each of the upper and lower surfaces of the copper clad laminate, and a via hole for electrical connection between the inner circuit pattern layer and the chip;
an insulating layer formed on each of the upper and lower surfaces of the core layer and having a via hole formed therethrough; and
an outer circuit pattern layer formed on the insulating layer.

2. The printed circuit board as set forth in claim 1, further comprising a polymer material filling a space of the hollow region other than a space occupied by the embedded chip.

3. The printed circuit board as set forth in claim 1, wherein the via hole of the core layer includes a through hole for electrical connection of the inner circuit pattern layers and a blind via hole for electrical connection of the chip and the inner circuit pattern layer.

4. An embedded chip printed circuit board, comprising:
a core layer, which includes a base substrate having upper and lower surfaces and a plurality of insulating layers and a plurality of circuit layers and having a hollow region opening at one of the upper and lower surfaces thereof, a chip embedded in the base substrate, an inner circuit pattern layer formed on each of the upper and lower surfaces of the base substrate, and a via hole for electrical connection between the inner circuit pattern layer and the chip;
an insulating layer formed on each of the upper and lower surfaces of the core layer and having a via hole formed therethrough; and
an outer circuit pattern layer formed on the insulating layer.

5. A method of manufacturing an embedded chip printed circuit board, comprising the steps of:
forming a hollow region at a surface of a copper clad laminate such that the hollow region opens at the surface thereof;
applying a polymer material on a bottom surface of the hollow region of the copper clad laminate;
placing a chip on the polymer material in the hollow region of the copper clad laminate;
filling a space of the hollow region other than a space occupied by the chip with a polymer material;
leveling a surface of the filled polymer material;
forming a via hole through the copper clad laminate having the chip;
plating the via hole;
forming an inner circuit pattern layer on the copper clad laminate using a photolithographic process;
laminating an insulating layer on the inner circuit pattern layer, forming a via hole; and
forming an outer circuit pattern layer using a semi-additive process.

6. The method as set forth in claim 5, wherein the step of forming of the hollow region is conducted by drilling the surface of the copper clad laminate.

7. The method as set forth in claim 5, further comprising the step of laminating a resin coated copper, having an insulating layer and a copper foil formed on either surface of the insulating layer, on the copper clad laminate, before the step of forming the hollow region.

8. The method as set forth in claim 5, wherein the step of forming the hollow region is conducted to be deeper than a height of the chip to be embedded.

9. The method as set forth in claim 5, wherein the step of forming the via hole includes the steps of:
forming a blind via hole for electrical connection of the chip and the inner circuit pattern layer through the polymer material; and
forming a through hole for electrical connection of the inner circuit pattern layers through the copper clad laminate.

10. The method as set forth in claim 5, wherein the step of plating the via hole is conducted by electroless copper plating and then copper electroplating the via hole.

11. The method as set forth in claim 5, wherein the polymer material is liquid epoxy material.

12. The method as set forth in claim 5, wherein the step of forming the outer circuit pattern layer includes the steps of:
forming a seed layer on the insulating layer having the via hole formed therethrough;
providing a dry film to be cured by ultraviolet (UV) light on the seed layer;
laminating an artwork film having a predetermined circuit pattern on the dry film;
radiating UV light onto the artwork film to cure the dry film;
removing the dry film uncured by UV light to open the seed layer;
electroplating the opened seed layer with copper to form a plating layer;
removing the dry film corresponding to a region separate from where the plating layer is formed, to form an outer circuit pattern layer; and
removing the seed layer corresponding to a region separate from where the outer circuit pattern layer is formed through etching.

13. A method of manufacturing an embedded chip printed circuit board, comprising the steps of:
forming a hollow region at a surface of a copper clad laminate such that the hollow region opens at the surface thereof;
applying a polymer material on a bottom surface of the hollow region of the copper clad laminate;
placing a chip on the polymer material in the hollow region of the copper clad laminate;
filling a space of the hollow region other than a space occupied by the chip with a polymer material and leveling a surface of the filled polymer material;
forming a via hole through the copper clad laminate having the chip and plating the via hole;
forming an inner circuit pattern layer on the copper clad laminate using a photolithographic process;
laminating a resin coated copper on the inner circuit pattern layer, forming a via hole;
plating or fill-plating the via hole; and
forming an outer circuit pattern layer on the resin coated copper using a photolithographic process.

14. The method as set forth in claim 13, wherein the step of forming the hollow region is conducted by drilling the surface of the copper clad laminate.

15. The method as set forth in claim 13, further comprising the step of laminating a resin coated copper, having an insulating layer with an upper and lower surface and a copper foil formed on either the upper or lower surface of the insulating layer, on the copper clad laminate, before the step of forming a hollow region.

16. The method as set forth in claim 13, wherein the step of forming the hollow region is conducted to be deeper than a height of the chip to be embedded.

17. The method as set forth in claim 13, wherein the step of forming the via hole includes the steps of:
forming a blind via hole for electrical connection of the chip and the inner circuit pattern layer through the polymer material; and
forming a through hole for electrical connection of the inner circuit pattern layers through the copper clad laminate.

18. The method as set forth in claim 13, wherein the plating of the via hole in the step of forming a via hole is conducted by electroless copper plating and then copper electroplating the via hole.

19. The method as set forth in claim 13, wherein the plating of the via hole in the step laminating the resin coated copper is conducted by electroless copper plating and then copper electroplating the via hole.

20. The method as set forth in claim 13, wherein the fill-plating of the via hole in the step laminating the resin coated copper is conducted by electroless copper plating and then copper electroplating the via hole.

21. The method as set forth in claim 13, wherein the polymer material is liquid epoxy material.
